(19) United States
(12) Patent Application Publication
(10) Pub. No.: US 2006/0204647 A1
(43) Pub. Date: Sep. 14, 2006

(54) De-icing system for driveways, walkways, sidewalks and other surfaces

(76) Inventor: Vittorio Calabrese, Old Bridge, NJ (US)

Correspondence Address: BENJAMIN APPELBAUM, PH.D.;ATTORNEY AT LAW, 27 BENNINGTON DRIVE, FLANDERS, NJ, 07836, US

(21) Appl. No.: 11/262,461

(22) Filed: Oct. 28, 2005

Related U.S. Application Data
(60) Provisional application No. 60/659,563, filed on Mar. 9, 2005.

(51) Int. Cl. C23C 16/52; B05C 11/00

(52) U.S. Cl. 427/8; 118/679; 118/666

(57) ABSTRACT

A system and method to deice or remove snow or ice accumulated on a surface comprises a weather sensor, control means, a compressor containing a deicing agent, a heater to heat the agent, a second deicing agent stored in a second storage tank in communication with the compressor, and a means for distributing the deicing agents through one or more zones, each zone including a sprinkler head and piping. When air temperature is below freezing and humidity exceeds 99%, the control means causes a deicing agent to be heated, and the heated agent distributed through a zone. The second agent is distributed through the zone, then a pressurized gas purges the zone of residual agents. This is repeated for each zone; after a specified time, air temperature and humidity are determined, and the cycle is repeated if needed.

### CROSS-REFERENCE TO RELATED APPLICATIONS

This application claims the benefit of U.S. Provisional Patent Application Ser. No. 60/659,563, filed 9 Mar. 2005, the contents of which are incorporated by reference herein in their entirety.

### FIELD OF THE INVENTION

Embodiments of this invention include a system for deicing of driveways, walkways, sidewalks and like surfaces that surround a residence or business. In particular, an embodiment of this invention includes a storage tank for holding a deicing solution, one or more sprinkler heads positioned proximate a surface to be deiced, a control unit, a weather station or sensor, and a compressor and source of compressed gas, connected by the appropriate plumbing and electrical connections, such that at specific weather conditions, a deicing solution can be dispensed, and the plumbing then purged of residual deicing solution, leaving the system ready for reuse without the sprinkler heads becoming frozen shut.

### BACKGROUND OF THE INVENTION

During winter months in parts of the northern hemisphere, many people can be found outside their home or apartment, laboriously wielding a snow shovel to remove snow from their driveways and walkways. Sometimes the local government sends a truck to plow the streets and/or deposit a melting agent, such as salt, on snow-covered and/or icy areas, but this does not solve the individual's problem of getting from their home to the plowed streets. The task of removing accumulated snow from driveways, walkways, and sidewalks is often accomplished by the individual performing hard, manual labor, using a snow shovel to scoop up, lift, and heave the snow to the sides. In addition to shoveling snow, operators of businesses face the added task of shoveling snow or depositing salt, sand or other traction promoting materials on sidewalks and walkways adjacent to their businesses to provide traction for employees, pedestrians and customers to safeguard against individuals slipping and possibly being injured. These types of shoveling tasks are physically demanding, so much so that people over the age of fifty are cautioned not to perform this laborious job as it can be dangerous, especially for those who are not physically fit. While some businesses and residences employ devices such as heating coils or place steam lines under their sidewalks, walkways and the like, to effect snow and ice removal, this approach is not commonly used. Thus, there is both a long-felt and unmet need for a device that can prevent snow and ice from accumulating on the pedestrian areas surrounding a structure, such as a residence, business, or the like.

### BRIEF SUMMARY OF THE INVENTION

An object of the present invention is to provide a deicing system which will be actuated automatically when the air temperature reaches a specified temperature and the air contains a specified moisture content.

Another object of the present invention is to provide a deicing system in which the pipes and sprinkler heads through which the deicing solution is dispensed are purged of residual deicing solution between uses.

Still another object of the present invention is to provide a deicing system which can be used as a stand-alone system, or which can be integrated into a lawn sprinkling system.

Another object of the present invention is to provide a deicing system that is durable and can withstand repeated use in low temperature environments.

An embodiment of the present invention is a system and method to deice or remove snow or ice accumulated on a surface comprises a weather sensor, control means, a compressor containing a deicing agent, a heater to heat the agent, a second deicing agent stored in a second storage tank in communication with the compressor, and a means for distributing the deicing agents through one or more zones, each zone including a sprinkler head and piping. When air temperature is below freezing and humidity exceeds 99%, the control means causes a deicing agent to be heated, and the heated agent distributed through a zone. The second agent is distributed through the zone, then a pressurized gas purges the zone of residual agents. This is repeated for each zone; after a specified time, air temperature and humidity are determined, and the cycle is repeated if needed.

An exemplary embodiment of the present invention is a system to reduce snow or ice accumulation on a surface, the system comprising:

a weather sensor, the weather sensor including a means for determining air temperature and a means for determining air moisture (humidity);

a control means in communication with the weather sensor;

an agent to reduce snow or ice accumulation on the surface, the agent having a freezing point and a boiling point;

a compressor, the compressor including a supply tank for the agent, the supply tank further comprising a means for heating the agent to a temperature between the freezing point and the boiling point, the compressor being in communication with the control means;

a means for distributing the agent, the means for distributing the agent being in communication with the compressor and the control means;

a zone, the zone in communication with the means for distributing the agent, and wherein the zone comprises a sprinkler head in fluid communication with the means for distributing the agent; and

a means for purging the distributed agent from the zone;

wherein when the weather sensor determines that the air temperature is less than a specified temperature and the humidity is greater than 99%, the control means is actuated and communicates with the means for heating to heat the agent, wherein the heated agent is water; the heated water being distributed to the zone for a period of time specified by the control means, and the control means actuates the means for purging the agent, the agent being purged from the zone for a period of time specified by the control means.

### BRIEF DESCRIPTION OF THE SEVERAL VIEWS OF THE DRAWING

FIG. 1 is an example illustrating, in an embodiment of the invention proximate to a residence, the deployment of sprinkler heads along the length of a driveway, walkways and a sidewalk, and representative surface coverage of the sprinkler heads.

FIG. 2 is a schematic diagram illustrating the deicing system.

FIG. 3 is a schematic diagram illustrating the controller unit.

FIG. 4 is a flow chart of the system logic.

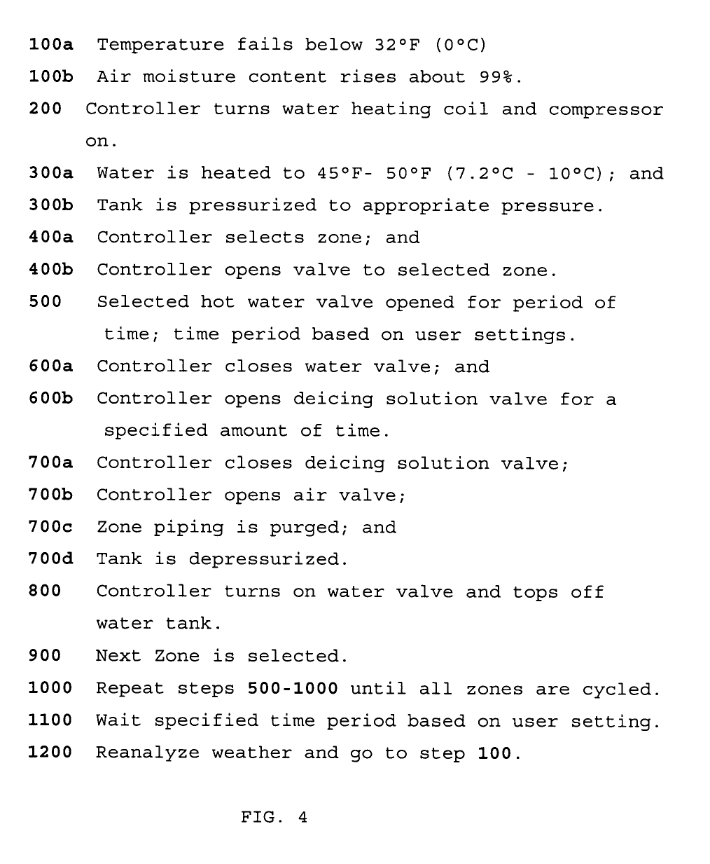

### DETAILED DESCRIPTION OF THE INVENTION

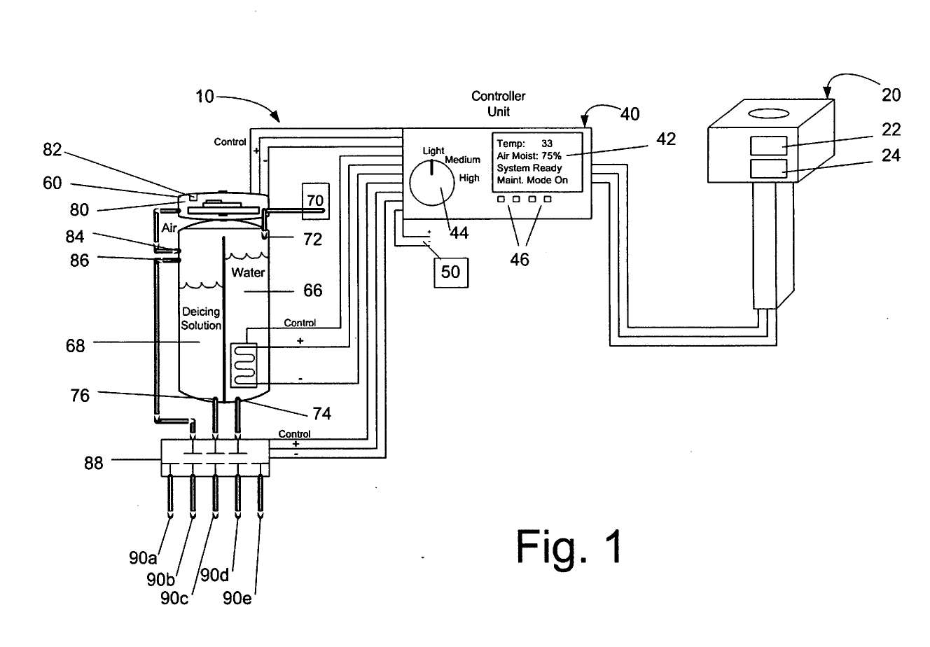

An embodiment of the present invention is shown FIG. 1. Deicing system 10 comprises a weather station (or sensor) 20, a controller unit 40, a compressor tank 60 which is in communication with a water supply 70 and an air supply 80. The compressor tank 60 is in communication with one or more zones 90a,-90e, with each zone comprising one or more sprinkler heads 92. The controller unit 40 is in electrical communication with the weather station 20, the compressor tank 60, and the actuators 88 which open the flow of air, deicing solution or water to the various zones 90a-90e.

The weather station (or sensor) 20 may generally be positioned in the outside environment, where air temperature and moisture content can be measured directly. However, depending upon the particular embodiment of weather station, the weather station 20 could be physically located inside a structure, providing the weather station 20 has probes that can be positioned outside to monitor the appropriate conditions, and transmit that data to weather station 20. The transmission of the temperature and air moisture can be done using either wired or wireless communications means, known to those skilled in the art.

Weather station 20 comprises a temperature probe or sensor 22 and a humidity/moisture sensor 24. Weather station 20 may include other functions, such as devices to measure the barometric pressure, wind speed and direction, and the like, but these are accessory functions not necessary for operation of this embodiment of the present invention.

The controller unit 40 is used to set the operating parameters of the deicing system 10. Controller unit 40 can be positioned outside of the structure, or may be positioned inside the structure. When controller unit 40 is located in the outside environment, it would be enclosed in a weather-protective casing, which casing can be opened by the user for access to the controls. Controller unit 40 includes a display 42, a deicing control 44 to adjust the amount of deicing solution to be dispensed, and one or more buttons 46, or other equivalent means, for setting the parameters of the system. In the embodiment illustrated in FIG. 1, control 44 is shown having three settings, designated at “Light”, “Medium” and “High”. In this embodiment, these settings are used for adjusting the output of the system to different weather events, such as, for example only and not intended as any limitation, “Light” to indicate a light snow coating, of less than about 2 inches; “Medium” to indicate a proposed snow accumulation of between from about 2 inches to about 6 inches of snow, and “High” for either a proposed snow accumulation of greater than 6 inches, or for a forecasted icing event. By adjusting control 44, the cycling of the water dispersal, deicer solution dispersal and the length of time of the off period can be varied. When the deicing system 10 is being installed, the water temperature needed for effective deicing will be calculated, and the system parameters set accordingly. Changes in the water temperature could be readjusted at a later date as the need arises. Buttons 46 can be buttons, switches, DIP switches, set screws, toggle switches, or other type of either electronic, electrical or electromechanical means for adjusting a control device.

Included within the body of the controller unit 40 is a microprocessor 48, a connection to a source 50 of electrical power, which could either be a battery or a connection to the building's power supply. An On-Off switch 98 is in communication with the source of electrical power, and with the microprocessor 48. Reference numeral 52 refers to the input from the weather station 20. The microprocessor 48 is in communication with the display 42, deicing control 44, buttons 46, and with one or more memories 54 and 56. The first memory 54 could be a read only memory, containing, for example only, factory-specified operating parameters and other defaults for the system, while the second memory 56 can be a random-access memory (“RAM”) to store user-specified commands. The microprocessor 48 is also in electrical communication with the outputs 58a-58c, which transmit to the compressor control means 62, heater 64, and the distribution means 88. Additional inputs and outputs could be built into the controller unit as needed. The inputs and outputs can be chosen form conventional means such as RS-232C, parallel, serial, small computer serial interface (“SCSI”), Universal Serial Bus (“USB”), IEEE 1394 (“Firewire”), phonoplugs, telephony, or other wired or wireless communications means now known or to be developed.

The heater 64 is used for heating the water, and the actuator means 88 functions in dispensing either air, water, and/or deicing solution to each zone 90a-90e, using the appropriate valves 94a-94e, respectively. The deicing solution, while not being specifically heated by its own heater, will generally be heated because of its' proximity to the heated water.

The controller unit 40, as well as the weather station 20, the compressor tank 60 and distribution means 82, can be fitted with a back-up battery for use in the event of a power failure. Such back-up batteries can be either conventional batteries such as alkaline or lithium batteries, rechargeable batteries such as nickel-cadmium, nickel-metal hydride or the like, or wet-cell storage batteries, as appropriate.

The compressor tank 60 can be partitioned such that one portion serves as a water tank 66 and the other serves as a deicing solution storage tank 68. An alternative embodiment can employ separate compressor tanks, one for water, one for the deicing solution, and, if necessary, another for compressed air, all in operative communication with the control unit and the actuators.

The compressor tank 60 is electronically operated, but could be operated by another source of electricity, such as a battery, a generator; or by using gasoline, kerosene, diesel fuel or the like.

The water supply 70 to the compressor tank is generally the same source of water used to supply the structure around which the deicing system 10 is dispersed. If the deicing system 10 is not being used near a structure, or an additional supply is needed for an embodiment positioned around a structure, the water supply 70 can originate from a well, municipal water source, storage tank, water tower, rainwater collection means, or other means of supplying water to the system. Water enters the compressor tank 60 by means of valve 72, and exits the compressor tank through exit valve 74. The deicing solution exits deicing solution tank 68 by through deicing exit valve 76.

The air supply 80 to the compressor tank is the air drawn in from the surrounding environment through a valve 82 on the compressor tank 60 and a second valve 84. When activated, air exits the compressor tank 60 through air exit valve 86. Alternatively, the air supply can be a separate source, such as an external compressed air tank or a pressure container, which is in communication with the compressor tank 60.

The deicing solution employed with the present invention is selected from those in current use today, or which may be developed in the future. Such deicing solutions can be chosen from a salt-water mixture, using salts such as rock salt, sodium chloride, potassium chloride, calcium chloride; compounds such as an aqueous solution of ethylene glycol, propylene glycol, alcohols. or mixtures thereof.

One or more conduits, such as tubing or piping 120 connects the outlet of the actuator block 88 with the sprinkler heads 92. The conduit can be selected from copper piping, cast iron piping, concrete piping, or plastic piping, such as polyvinyl chloride (“PVC”) piping, high density polyethylene (“HDPE”), low density polyethylene (“LDPE”) or other materials commonly employed by those skilled in the art, or to be developed in the future. In one embodiment, the piping 120 is buried underground; the type of piping chosen may also be dependent upon anticipated environmental conditions and local building codes. Conventional items, such as plumbing fittings, elbows, tees, and other connectors, and the structure of the sprinkler heads, are not shown in the drawings for purposes of clarity.

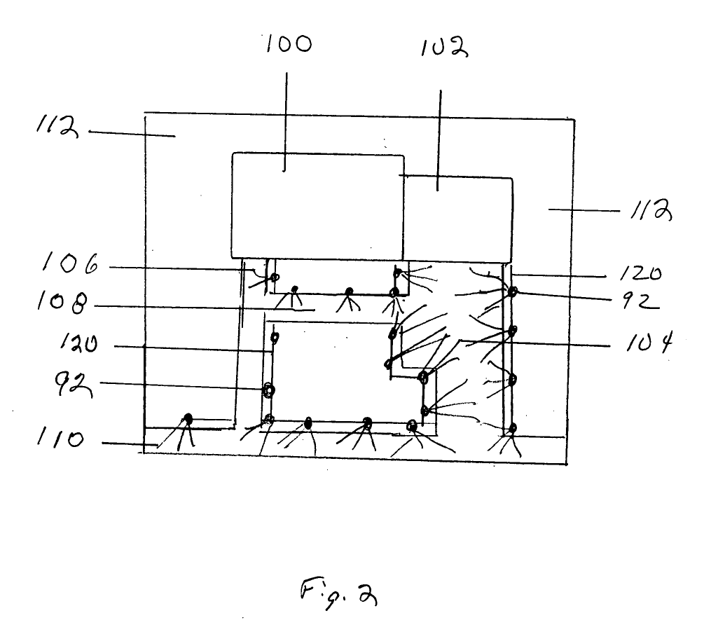

FIG. 2 illustrates one example of deicing system 10 deployed around a residence 100. The residence includes an attached garage 102, a driveway 104, walkways 106, 108 and a sidewalk 110. For purposes of example only, the remainder of the property is covered with grass 112. A plurality of sprinkler heads 92 are dispersed along the length of the driveway, walkways and the sidewalk, and in this example, the system is divided into four zones, zone 90a for the driveway 104, zone 90b for walkway 106, zone 90c for walkway 108 and zone 90d for sidewalk 110.

The sprinkler heads 92 are aimed at the driveway 104, walkways 106, 108 and sidewalk 110 rather than aimed at the grass 112. The sprinkler heads 92 are connected by conduits 120. The weather station 20, controller unit 40, and compressor tank 60 are not shown in this figure, but can be positioned either inside or outside the residence or garage, as determined by the user. The deicing solution is dispensed by the sprinkler heads onto the areas of coverage (sidewalks, driveways, walkways) and would prevent snow and ice from building up in areas that are covered by the sprinklers.

As used within the context of the present specification, the terms driveway, walkway and sidewalk are meant to include the general terminology used to describe such surfaces, and is also intended to include surfaces that may be either paved; unpaved; covered with dirt, rock, gravel or the like; made of concrete; stones such as paving stones, flagstone and the like; brick; various types of block; wood; composite lumber and/or wood-like materials; or paved with asphalt or the like, or concrete, or mixtures thereof as used for driveway, highway or road paving.

Also, the term “ice”, as used herein, is intended to cover frozen precipitation, such as freezing rain, molten snow which has frozen, ice in its conventional meaning, sleet and hail. The term “snow” as used herein is also intended to include snow in its conventional meaning, and sleet, because sleet may freeze and turn to ice, yet accumulate to depths comparable to snow accumulations, depending upon the weather conditions.

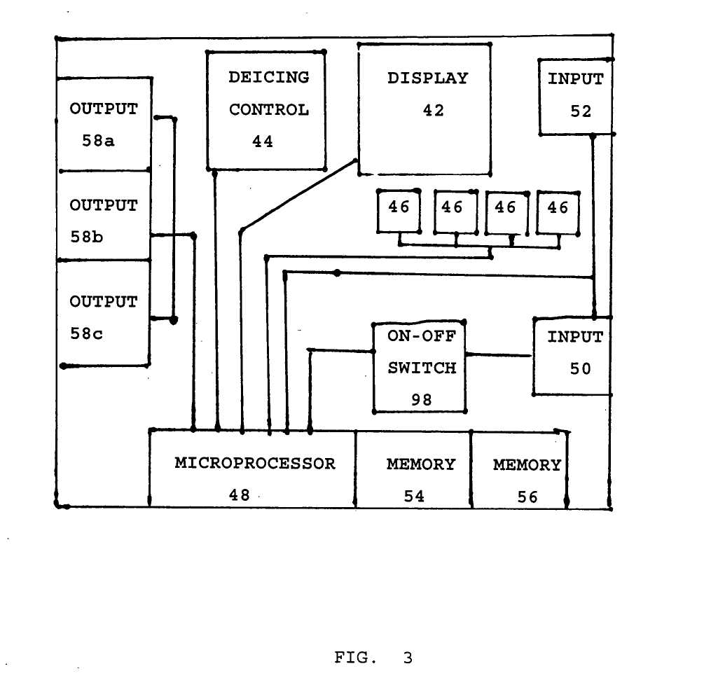

The operation of the deicing system 10 is shown in FIG. 3. At 100, the controller determines whether the outside temperature is below 32° F. (0° C.) and whether the air moisture content exceeds 99%. If the answer to both is Yes, at 200 the controller turns the water heater 64 and compressor 60 on. At 400a, the water is heated to a temperature that is above the freezing point but below the boiling point of the water. Thus, the water is heated to a temperature that ranges from about 33 degrees F. (0.6 degrees C.) to about 210 degrees F. (99.9 degrees C.); the water is heated to a temperature that preferably ranges from about 35 degrees F. (1.7 degrees C.) to about 150 degrees F. (65.6 degrees C.), more preferably ranges from about 40 degrees F (4.4 degrees C.) to about 100 degrees F. (37.8 degrees C.), and most preferably ranges from about 45 degrees F. (7.2 degrees C.) to about 60 degrees F. (15.6 degrees C.). In another embodiment, the water is heated to a temperature ranging from about 45° F. (7.2 degrees C.) to about 50° F. (10 degrees C.). The specific temperature range for the heated water is affected by the outside air temperature, and the distance that the water in the various zones has to travel from the location of the water tank to the sprinkler head. Thus, while a temperature range of between 45 degrees F. (7.2 degrees C.) to about 50 degrees F. (10 degrees C.) is specified herein for one embodiment, this range may actually be wider because of environmental conditions. At 400b the tank is pressurized to a pressure that is sufficient to distribute the solutions across the site for the desired time. The pressure can be affected by factors such as the type and diameter of the conduits, the number of sprinkler heads in a zone, and the size of the various zones. Generally, the pressure will range from about 50 psi (384.7 kPa) to about 200 psi (1379 kPa). In one embodiment, the pressure can range from about 100 psi (689.5 kPa) to about 130 psi (896.3 kPa), with a pressure of 120 psi (827.4 kPa) being effective.

At 500a, the controller selects which zone will be deiced, based on how the controller 40 was programmed, and at 500b the controller opens the outlet valve to the selected zone. At 600, the selected hot water valve is opened for period of time. The time period which the hot water valve is opened is specified by the user. After the specified time period has elapsed, at 700a the controller then closes water valve; and then (700b) the controller opens deicing solution valve for a specified amount of time. Once the specified deicing period has elapsed, at 800a the controller closes deicing solution valve, and at 800b the controller then opens air valve such that (800c) the piping to that zone is purged of residual liquid; and then, at 800d, the tank is depressurized. In the interim (900) the controller turns on the valve from the water supply and refills, or “tops off” the water tank. At step 1000, the next zone to be treated is selected by the controller, and at 1100, steps 600-1100 are repeated until all the zones in the system have been cycled. Once all of the zones have been treated, at 1200 the system waits for a specified time period, determined either by the user, by the system's defaults, or other parameters programmed into the controller, such that at 1300, the system will reanalyze the weather conditions and proceed to step 100, repeating the process as needed, and thereby prevent snow and ice buildup along the treated surfaces, and/or facilitate the removal of accumulated snow and ice.

It is anticipated that embodiments of the present invention can be installed using equipment similar to that used for installation of automatic lawn sprinkler systems. An existing sprinkler system could be upgraded to a deicing system by addition of elements of the present invention, such as, but not limited to, the compressor tank 60, the controller unit 40 and the weather station 20, either alone or in combination, using fittings compatible with the underground piping and sprinkler heads already in place. A changeover from an automatic sprinkling system to a deicing system would require changing the direction of the sprinkler heads, and this could be performed by either the user or a service technician.

Although this invention has been described as being applicable to use around either residential or commercial structures or properties, components of the system could be scaled up or down in size such that alternative embodiments could be used upon a variety of other surfaces which often require deicing. Examples of other commercial areas in which this system could be deployed include loading docks, parking lots, railroad tracks, stairs, steps, ramps, decks, security barriers, fire escapes and roofs. An embodiment of this invention could be installed on a railroad car, and used to deice a length of railroad track. Such use on a railroad may be of particular importance in regions where the railroad tracks go through mountainous areas that are often subject to closing because of snow and ice accumulation on the tracks. Embodiments of this system could also be used in the aviation industry, on areas such as tarmacs, taxiways, runways, landing strips, helipads, and smaller embodiments mounted on aircraft for deicing of aircraft surfaces such as aircraft engines, aircraft wings, aircraft tails, helicopters, and helicopter rotors.

Therefore, although this invention has been described with a certain degree of particularity, it is to be understood that the present disclosure has been made only by way of illustration, and that numerous changes in the details of construction and arrangement of parts may be resorted to without departing from the spirit and scope of the invention.

I claim:

1. A system to reduce snow or ice accumulation on a surface, the system comprising:
a weather sensor, the weather sensor including a means for determining air temperature and a means for determining air moisture (humidity);
a control means in communication with the weather sensor;
an agent to reduce snow or ice accumulation on the surface, the agent having a freezing point and a boiling point;
a compressor, the compressor including a supply tank for the agent, the supply tank further comprising a means for heating the agent to a temperature between the freezing point and the boiling point, the compressor being in communication with the control means;
a means for distributing the agent, the means for distributing the agent being in communication with the compressor and the control means;
a zone, the zone in communication with the means for distributing the agent, and wherein the zone comprises a sprinkler head in fluid communication with the means for distributing the agent; and
a means for purging the distributed agent from the zone;
wherein when the weather sensor determines that the air temperature is less than a specified temperature and the humidity is greater than 99%, the control means is actuated and communicates with the means for heating to heat the agent, wherein the heated agent is water; the heated water being distributed to the zone for a period of time specified by the control means, and the control means actuates the means for purging the agent, the agent being purged from the zone for a period of time specified by the control means.

2. The system as described in claim 1, further comprising a second supply tank, the second supply tank being in communication with the compressor and the control means.

3. The system as described in claim 2, wherein the compressor further comprises the second supply tank.

4. The system as described in claim 2, further comprising a second agent, the second agent being stored in the second supply tank, and wherein the second agent is selected from the group consisting of aqueous solutions of sodium chloride, potassium chloride, rock salt, glycol, ethylene glycol, propylene glycol or alcohol, or mixtures thereof,

5. The system as described in claim 3, wherein after the heated water has been distributed to the zone, and before the means for purging the agent is distributed to the zone, the control means actuates the means for distributing, and the second agent is distributed to the zone for a period of time specified by the control means.

6. The system as described in claim 5, wherein the means for purging comprises a pressurized gas, and wherein the pressurized gas is distributed to the sprinkler head by a conduit, the conduit in communication with the means for distributing and the sprinkler head, thereby purging the agents from the conduit and the sprinkler head after the agents have been distributed through the conduit and sprinkler head.

7. The system as described in claim 5, further comprising a water source, the water source in communication with the water supply tank, and wherein after the heated water has been distributed to the zone, water from the water source is transferred to the water supply tank to top off the water supply tank in response to communication from the control means.

8. The system as described in claim 5, wherein the surface is selected from the group consisting of walkways, driveways, sidewalks, runways, landing strips, helipads, streets, highways, roadways, docks, loading docks, parking lots, railroad tracks, stairs, steps, ramps, decks, security barriers, fire escapes, roofs, aircraft, aircraft engines, aircraft wings, helicopters and helicopter rotors.

9. The system as described in claim 8, wherein the surface is selected from the group consisting of walkways, driveways and sidewalks.

10. The system as described in claim 5, wherein the water is heated to a temperature ranging from about 33 degrees F. (0.6 degrees C.) to about 210 degrees F. (99.9 degrees C.).

11. The system as described in claim 10, wherein the water is heated to a temperature ranging from about 35 degrees F. (1.7 degrees C.) to about 150 degrees F. (65.6 degrees C.).

12. The system as described in claim 11, wherein the water is heated to a temperature ranging from about 40 degrees F. (4.4 degrees C.) to about 100 degrees F. (37.8 degrees C.).

13. The system as described in claim 12, wherein the water is heated to a temperature ranging from about 45 degrees F. (7.2 degrees C.) to about 60 degrees F. (15.6 degrees C.).

14. The system as described in claim 5, wherein the means for determining temperature and the means for determining air moisture are positioned remotely from the weather sensor, and wherein the means for determining temperature and the means for determining air moisture communicate with the weather sensor by a means for communicating selected from the group consisting of wired and wireless means for communicating, or a combination thereof.

15. A system to deice a surface, the system comprising:
a weather sensor, the weather sensor including a means for determining air temperature and a means for determining air moisture (humidity);
a control means in communication with the weather sensor, the means for determining temperature and the means for determining air moisture in communication with the weather sensor by a means for communicating selected from the group consisting of wired and wireless means for communicating, or a combination thereof;
one or more agents to deice the surface, each said agent having a freezing point and a boiling point;
a compressor, the compressor including a supply tank for a first agent, the supply tank further comprising a means for heating the first agent to a temperature between the freezing point and the boiling point, the compressor being in communication with the control means;
a second supply tank, the second supply tank comprising a second agent, the second supply tank being in communication with the compressor and the control means;
a means for distributing the agents, the means for distributing the agents being in communication with the compressor and the control means;
one or more zones, each said zone being in communication with the means for distributing the agents, each said zone comprising a sprinkler head in fluid communication with the means for distributing the agents; and
a means for purging the distributed agents from the zones;
wherein when the weather sensor determines that the air temperature is less than the freezing point of water and the humidity is greater than 99%, the control means is actuated and communicates with the means for heating to heat the first agent, the heated first agent being water, the water being heated to a temperature ranging from about 33 degrees F. (0.6 degrees C.) to about 210 degrees F. (99.9 degrees C.);
the heated water being distributed to a first zone for a period of time specified by the control means, the control means actuating the second agent supply tank and the means for distributing to distribute the second agent to the first zone, and the control means actuating the means for purging the agents, the agents being purged from the first zone for a period of time specified by the control means.

16. The system as described in claim 15, further comprising a second agent, and wherein the second agent is selected from the group consisting of aqueous solutions of sodium chloride, potassium chloride, rock salt, glycol, ethylene glycol, propylene glycol or alcohol, or mixtures thereof.

17. The system as described in claim 16, wherein the means for purging comprises a pressurized gas, and wherein the pressurized gas is distributed to the sprinkler head zone by a conduit, the conduit in communication with the means for distributing and the sprinkler head, thereby purging the agent from the conduit and the sprinkler head after the agents have been distributed through the conduit and sprinkler head.

18. The system as described in claim 17, wherein the surface is selected from the group consisting of walkways, driveways and sidewalks.

19. The system as described in claim 16, wherein the water is heated to a temperature ranging from about 33 degrees F. (0.6 degrees C.) to about 210 degrees F. (99.9 degrees C.).

20. A method to reduce snow and ice accumulation on a surface, the method comprising the steps of:
determining whether the air temperature is less than a specified temperature and determining whether the humidity is greater than 99%, by utilizing a weather sensor, the weather sensor including a means for determining the air temperature and a means for determining the air moisture (humidity);
causing a control unit to actuate a compressor when the air temperature is below the specified temperature and the humidity is greater than 99%, wherein the control unit is in communication with the weather sensor, and wherein the compressor includes a supply tank for an agent to reduce snow or ice accumulation, the agent having a freezing point and a boiling point, and the supply tank further includes a means for heating the agent to a temperature between the freezing point and the boiling point;
causing the control unit to actuate the means for heating the agent, the agent being water;
pressurizing the compressor to a specified pressure range, the specified pressure range being sufficient to distribute the deicing agent through a means for distributing, the means for distributing being in communication with the compressor and the control unit;
distributing the heated water to a zone through the means for distributing for a period of time specified by the control unit, wherein the zone comprises a sprinkler head in fluid communication with the means for distributing;
distributing a means for purging to the zone through the means for distributing for a period of time sufficient to purge the zone of residual agent; and
depressurizing the compressor when the period of time has elapsed.

21. The method as described in claim 20, wherein the compressor further comprises a second supply tank, the second supply tank being in communication with the compressor and the control means.

22. The method as described in claim 21, further comprising the step of distributing a second agent to the zone for a period of time specified by the control means after the heated water has been distributed to the zone, and before the pressurized gas is distributed to the zone.

23. The method as described in claim 22, wherein the second agent is selected from the group consisting of aqueous solutions of sodium chloride, potassium chloride, rock salt, glycol, ethylene glycol, propylene glycol or alcohol, or mixtures thereof.

24. The method as described in claim 20, further comprising the step of topping off the supply tank for the water in response to communication from the control means after the heated water has been distributed to the zone, wherein the supply tank is in communication with a water source.

25. The method as described in claim 21, wherein the surface is selected from the group consisting of walkways, driveways, sidewalks, runways, landing strips, helipads, streets, highways, roadways, docks, loading docks, parking lots, railroad tracks, stairs, steps, ramps, decks, security barriers, fire escapes, roofs, aircraft, aircraft engines, aircraft wings, helicopters and helicopter rotors.

26. The method as described in claim 21, further comprising the step of heating the water to a temperature ranging from about 33 degrees F. (0.6 degrees C.) to about 210 degrees F. (99.9 degrees C.).

27. The method as described in claim 26, further comprising the step of heating the water to a temperature ranging from about 35 degrees F. (1.7 degrees C.) to about 150 degrees F. (65.6 degrees C.).

28. The method as described in claim 27, further comprising the step of heating the water to a temperature ranging from about 40 degrees F. (4.4 degrees C.) to about 100 degrees F. (37.8 degrees C.).

29. The method as described in claim 28, further comprising the step of heating the water to a temperature ranging from about 45 degrees F. (7.2 degrees C.) to about 60 degrees F. (15.6 degrees C.).

30. The method as described in claim 22, further comprising the step of selecting a second zone to reduce snow or ice accumulation on the surface.

31. The method as described in claim 30, further comprising the step of repeating the steps of claims 20 through 30 until all zones comprising the system have been deiced.

32. The method as described in claim 31, further comprising the step of waiting a specified period of time after the last zone has been deiced, and determining whether the air temperature is below the freezing point of water and whether the moisture content of the air is greater than 99%; and repeating the method of claims 20 through 31.

33. A method for deicing a surface, the method comprising the steps of:
determining whether the air temperature is less than a specified temperature and determining whether the humidity is greater than 99%, by utilizing a weather sensor, the weather sensor including a means for determining the air temperature and a means for determining the air moisture (humidity);
causing a control unit to actuate a compressor when the air temperature is below the specified temperature and the humidity is greater than 99%, wherein the control unit is in communication with the weather sensor, and wherein the compressor includes a supply tank for an agent to reduce snow or ice accumulation, the agent having a freezing point and a boiling point, and the supply tank further includes a means for heating the agent to a temperature ranging from about 33 degrees F. (0.6 degrees C.) to about 210 degrees F. (99.9 degrees C.);
causing the control unit to actuate the means for heating the agent, the agent being water;
pressurizing the compressor to a specified pressure range, the specified pressure range being sufficient to distribute the deicing agent through a means for distributing, the means for distributing being in communication with the compressor and the control unit;
distributing the heated water to a zone through the means for distributing for a period of time specified by the control unit, wherein the zone comprises a sprinkler head in fluid communication with the means for distributing;
distributing a second agent to the zone through the means for distributing for a period of time specified by the control unit, wherein the second agent is stored in a second supply tank, and the second agent supply tank is in communication with the compressor and the control means;
distributing a means for purging to the zone through the means for distributing for a period of time sufficient to purge the zone of residual agent; and
depressurizing the compressor when the period of time has elapsed.

34. The method as described in claim 33, wherein the second agent is selected from the group consisting of aqueous solutions of sodium chloride, potassium chloride, rock salt, glycol, ethylene glycol, propylene glycol or alcohol, or mixtures thereof.

35. The method as described in claim 33, wherein the surface is selected from the group consisting of walkways, driveways, sidewalks, runways, landing strips, helipads, streets, highways, roadways, docks, loading docks, parking lots, railroad tracks, stairs, steps, ramps, decks, security barriers, fire escapes, roofs, aircraft, aircraft engines, aircraft wings, helicopters and helicopter rotors.

36. The method as described in claim 33, further comprising the step of heating the water to a temperature ranging from about 35 degrees F. (1.7 degrees C.) to about 150 degrees F. (65.6 degrees C.).

37. The method as described in claim 33, further comprising the step of selecting a second zone to be deiced.

38. The method as described in claim 37, further comprising the step of repeating the steps of claims 33 through 37 until all the zones have been deiced.

39. The method as described in claim 37, further comprising the step of waiting a specified period of time after the last zone has been deiced, and determining whether the air temperature is below the freezing point of water and whether the moisture content of the air is greater than 99%; and repeating the method of claims 33 through 39.
